(19) United States
(12) Patent Application Publication
(10) Pub. No.: US 2009/0321946 A1
(43) Pub. Date: Dec. 31, 2009

(54) PROCESS FOR FABRICATING AN INTEGRATED ELECTRONIC CIRCUIT INCORPORATING A PROCESS REQUIRING A VOLTAGE THRESHOLD BETWEEN A METAL LAYER AND A SUBSTRATE

(75) Inventor: Laurent G. Gosset, Grenoble (FR)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/375,884

(22) PCT Filed: Jul. 31, 2007
(86) PCT No.: PCT/IB2007/053021

§ 371 Date: Jan. 30, 2009

(30) Foreign Application Priority Data
Aug. 1, 2006 (EP) 06300848.6

(51) Int. Cl. H01L 23/48; H01L 21/68; H01L 21/768

(52) U.S. Cl. 257/774; 438/637; 257/758; 438/618; 257/E23.011; 257/E21.575

(57) ABSTRACT

A process for fabricating an electronic integrated circuit comprising a multi-layer interconnect stack. A structure (26), such as a MIM capacitor is formed by means of a process that requires the generation of a localized voltage across a nearby primary interconnect line (36) to the substrate. A secondary interconnect path (42) is provided which intersects with the primary interconnect line (36), which is removed after the structure (26) has been formed, so as to create an open circuit in the primary interconnect line (36). Thus, the performance of the circuit is enhanced.

This invention relates generally to a process for fabricating an integrated electronic circuit incorporating a process (such as ECD or pore formation) requiring a voltage threshold between a metal layer at the wafer surface and the semiconductor substrate.

As ULSI devices shrink in size and high-level integration becomes more complex, Cu is expected to replace Al alloys for ultra large-scale integration (ULSI) interconnections. The dual-damascene fabrication process is presently recognised as a standard interconnection technique, in which metallic barrier layers and Cu seed layers are deposited in that order on the inside walls of via holes or trenches using a sputtering method (physical vapour deposition (PVD)), and Cu interconnections are then embedded into the via holes or trenches using an electrochemical deposition (ECD) method.

There are many applications in which it is required to generate a voltage threshold between a metal layer formed at the surface of the wafer and the semiconductor substrate. For example, it may be required to integrate a passive component such as a MIM (Metal-Insulator-Metal) capacitor with active or CMOS transistors in modern VLSI devices, and it is known to form a MIM capacitor at one of the metal layers of a multilevel interconnect stack using a process that includes generating a voltage threshold across a conductive path provided between a metal layer formed at the surface of the wafer and a nearby interconnect to the substrate. In general, however, there are many other operations, e.g. pore formation, in which a threshold voltage is required to be generated between an upper metal layer and the semiconductor substrate, such operations being typically associated with wet chemistry at the wafer surface combined with a voltage, and this threshold voltage is conventionally provided across a multilayer interconnect structure (typically Al or Cu, although other conductive materials may be considered) between the surface of the wafer at which the metal layer is provided and the substrate (usually via a tungsten (W) plug).

In a known dual damascene structure, including for example a MIM capacitor formed in this manner, the interconnect between the capacitor and the substrate remains in situ after formation of the capacitor is completed. However, such an interconnect path contributes nothing to the overall functionality of the structure and, in fact, acts as an antenna for parasitic signals, that could lead to malfunction of the structure.

It is therefore preferred to provide a process for fabricating an electronic integrated circuit wherein an interconnect path is provided between the wafer surface and the semiconductor substrate in order to provide therebetween a threshold voltage required for a specific processing step, and wherein said interconnect path is subsequently broken.

In accordance with the present invention, there is provided a method of fabricating an electronic integrated circuit comprising providing at least one dielectric layer on a substrate, forming a primary metallic interconnect line from a first location through said dielectric layer to said substrate and a second interconnect path from said primary interconnect line to a second location, different from said first location, creating a structure adjacent said primary interconnect line by performing a process step that includes the step of generating a voltage across said primary interconnect line, and removing, via said second interconnect path, at least a portion of said primary interconnect line at the intersection between said primary interconnect line and said second interconnect path so as to form an open circuit in said primary interconnect line.

Thus, where it is required to form a structure by means of a process that requires a locallized voltage threshold to be provided via the primary interconnect line, that interconnect line can subsequently be broken via the second interconnect line so as to prevent the adverse performance effects that would otherwise be caused thereby.

In a first exemplary embodiment, the integrated circuit comprises a multi-layer interconnect stack, wherein said first and second locations from which said primary interconnect line and second interconnect path respectively extend are laterally spaced from each other at an upper surface of the same interconnect layer n. In this case, the structure is preferably formed by creating an exposed area on said primary interconnect line at said first location, and forming said structure in the next interconnect layer n+1 of said stack. The second interconnect path may extend substantially vertically into the dielectric layer of the interconnect layer n and then substantially horizontally to intersect with said primary interconnect line.

Alternatively, the structure may be formed alongside the primary interconnect line.

The second interconnect path and intersecting portion of the primary interconnect line may be removed by any suitable process, for example, chemical etching or a reverse metal electropolishing process.

These and other aspects of the present invention will be apparent from, and elucidated with reference to, the embodiments described herein.

Embodiments of the present invention will now be described by way of examples only and with reference to the accompanying drawings, in which:

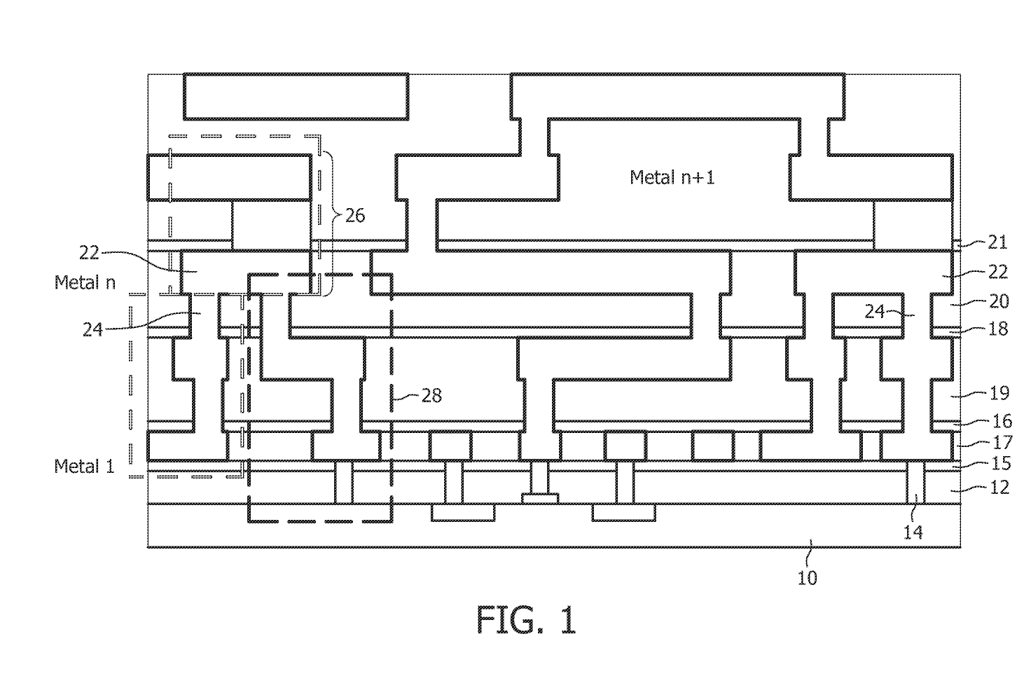

FIG. 1 is a schematic cross-sectional view of a multi-layer interconnect stack including MIM capacitors formed in the Metal n+1 layer;

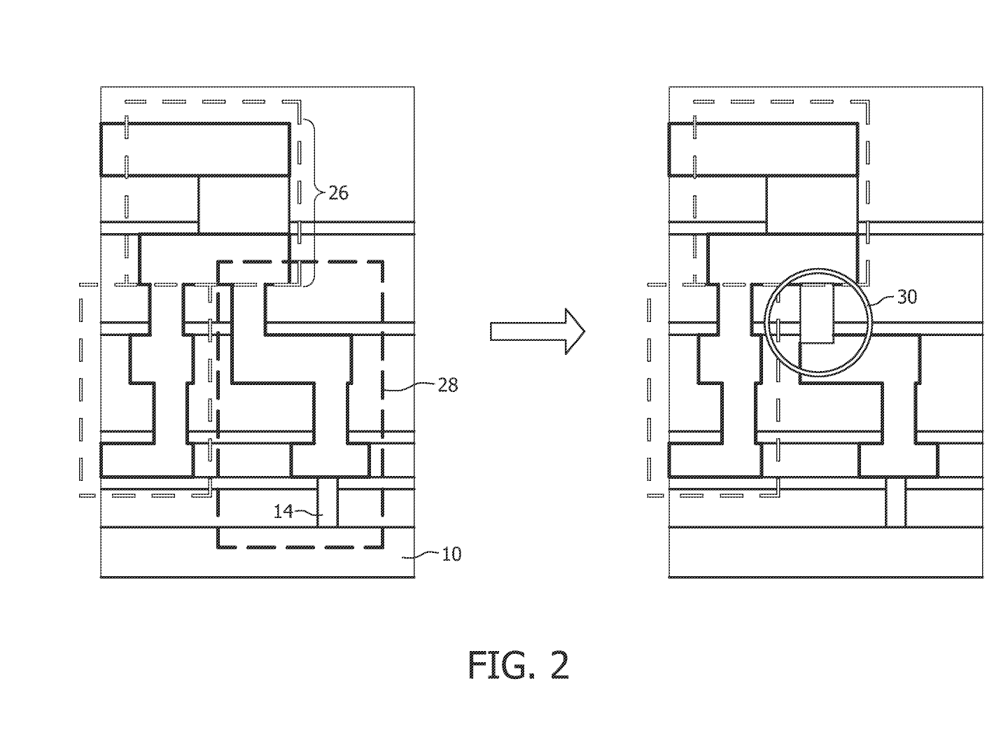

FIG. 2 is a schematic cross-sectional view representing the requirement for a break in the primary interconnect line;

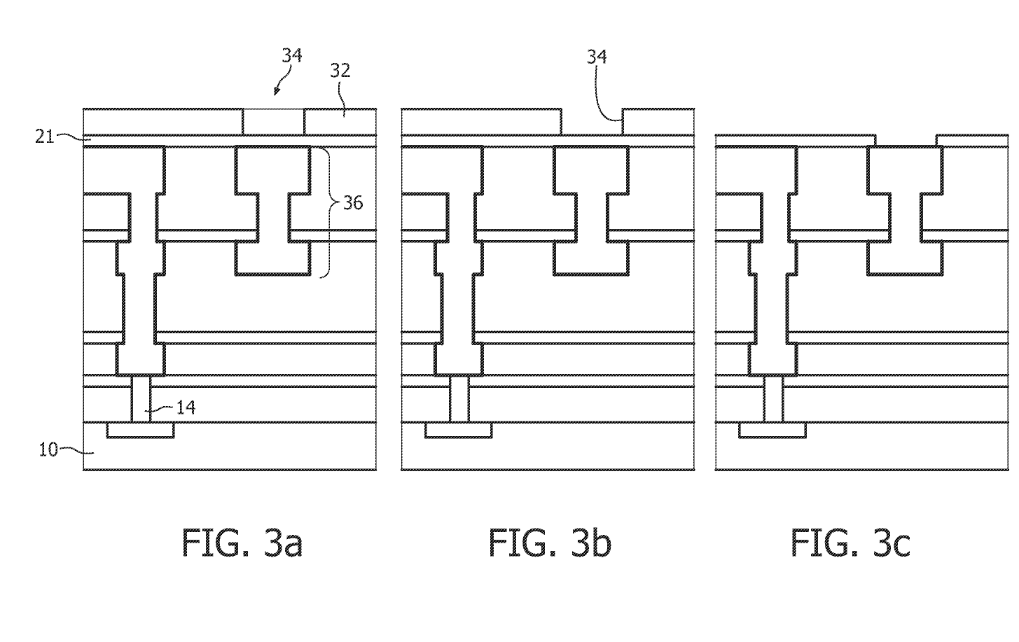

FIG. 3 is a schematic cross-sectional partial view of an interconnect stack illustrating exposure of the primary interconnect line;

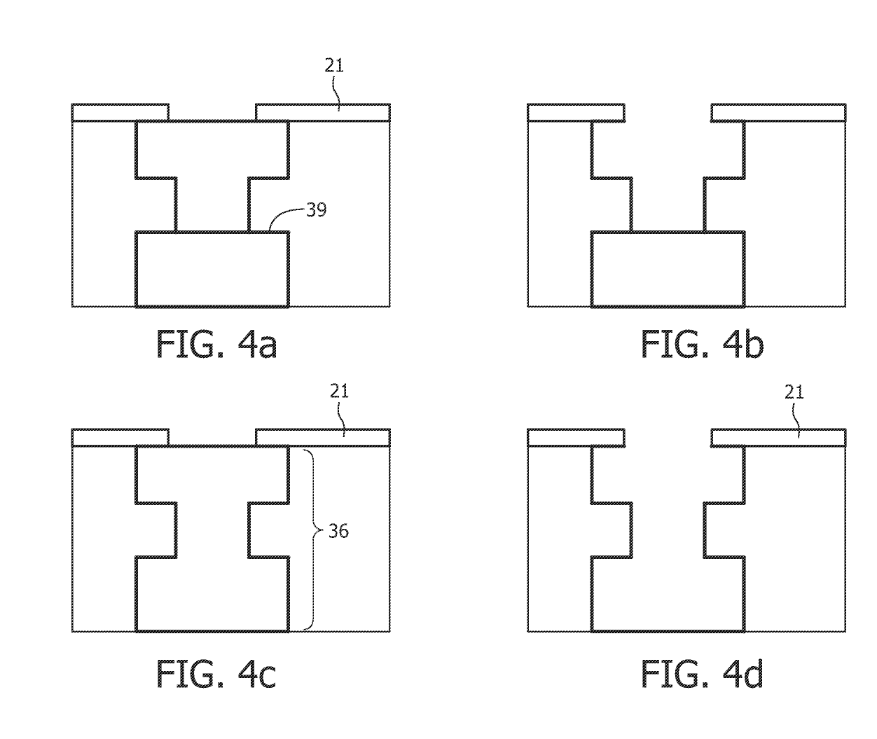

FIGS. 4(a)-(d) illustrate schematically the process of selective chemical removal of Cu in the case where there is a Cu-barrier interface at via level ((a), (b)) and the case where there is a Cu—Cu interface at via level ((c), (d));

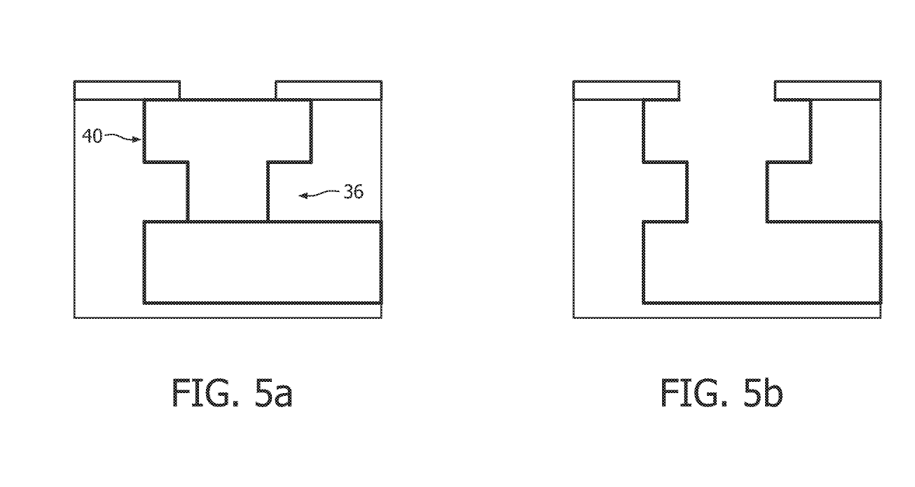

FIG. 5 illustrates schematically the provision of dielectric liners prior to non-selective chemical Cu removal;

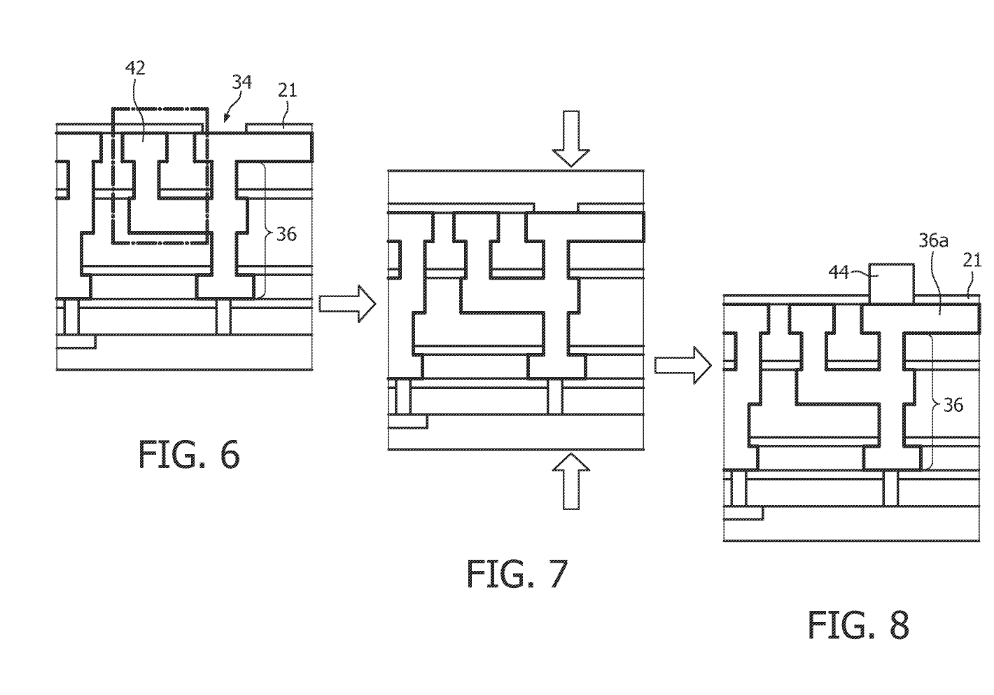

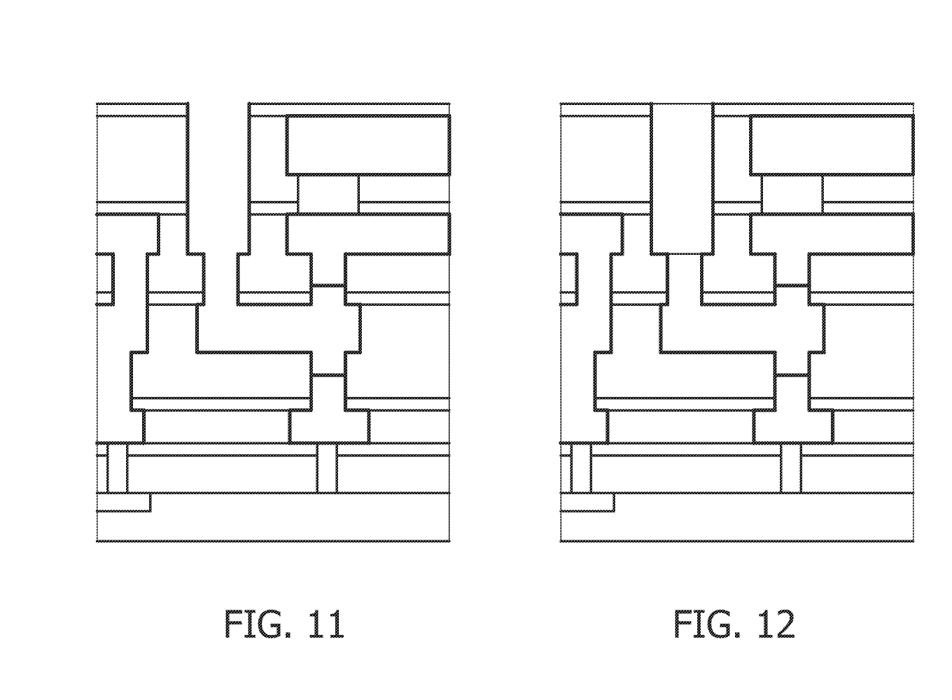

FIGS. 6 to 12 illustrate schematically the principal process steps of a method of fabrication according to a first exemplary embodiment of the present invention; and

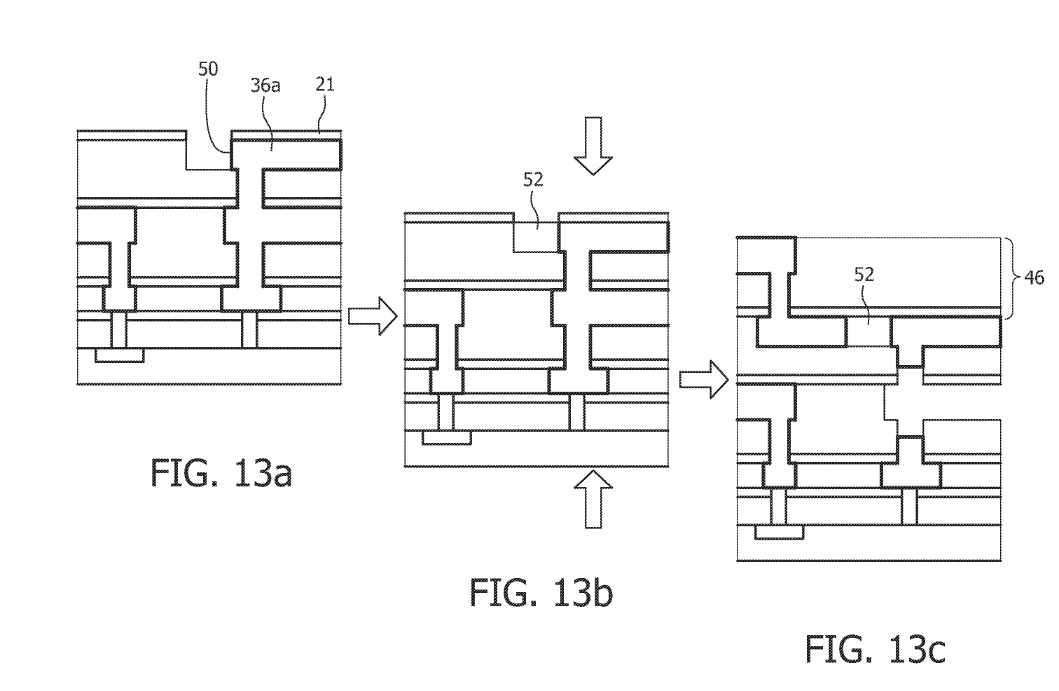

FIG. 13 illustrate some of the principal process steps of a method of fabrication according to a second exemplary embodiment of the present invention.

As CMOS transistor scaling proceeds into the deep sub-micron regime, the number of transistors on high performance, high-density Ics is in the tens of millions. The signal integration of this many active elements has necessitated that such Ics feature as many as eight layers of high density metal interconnect. In the past, such metal interconnects have typically been formed of Aluminium with Silicon Dioxide dielectric between the lines, but more recently, copper metal is being commonly used with low-k dielectric materials because copper reduces the resistance of the metal interconnect lines (and increases their reliability), while low-k dielectrics reduce the parasitic capacitance between the metal lines. These new materials are employed in a fabrication process known as “Dual Damascene” which is used to create the multi-level, high density metal interconnections needed for advanced, high performance Ics.

In a dual damascene technique overcomes this problem by etching a columnar hole, followed by a trench etch into the inter-layer dielectric (ILD) and then filling both structures with copper which is subsequently polished back (using chemical mechanical polishing (CMP)) to the surface of the ILD. The result is a vertical copper via connection and an inlaid copper metal line. Thus, referring to FIG. 1 of the drawings, a typical semiconductor fabrication process may comprise a front end process to form one or more transistors in layer 10, following which an inter-layer dielectric layer 12 is deposited and tungsten (W) plugs 14 are formed as a the contacts to the semiconductor substrate (not shown). Next, a copper line 15, a first low-k ILD 17, a first silicon nitride barrier layer 16, a second low-k ILD 19, a second silicon nitride barrier layer 18, a third low-k ILD 20 and a third silicon nitride layer 21 are provided in that order to create a multi-layer stack.

Trenches 22 and vias are formed by applying photoresist to the wafers, lithographically patterning the photoresist and then and then etching, prior to stripping the photoresist layer. The third silicon nitride layer 21 provides a surface hard mask on top of the third ILD 20 so as to protect the ILD from the subsequent photoresist stripping process. This is because the low-k materials that form the ILD are susceptible to the same chemistries that strip photoresist. In addition, the surface hard mask 21 acts as a CMP stop during subsequent copper polishing.

Next, a thin Tantalum barrier is deposited which lines the Dual Damascene structure and acts as a barrier to prevent the copper (deposited in the next operation) from diffusing into the ILD. A copper seed is next deposited using PVD and the bulk copper is deposited via electroplating. The copper is then polished back using CMP to the surface of the trenches, a thin silicon nitride barrier is deposited on top of it and the dual damascene structure is thus completed.

In FIG. 1, a multi-level interconnect stack is illustrated that includes MIM capacitors 26 at the Metal n+1 level, wherein in order to perform the electrochemical deposition (ECD) process required to deposit the bulk metal, it is required to generate a voltage threshold between the Metal n layer and the substrate. In the case of the left-hand MIM capacitor, this is provided by the interconnect structure highlighted by reference numeral 28.

More generally, however, and as explained above, the application of the present invention is more widely applicable to any process that requires an electrical connection to the Si substrate to facilitate a threshold voltage for a specific process, for example, ECD for depositing Cu, formation of pores within a matrix, etc. Such processes are typically associated with wet chemistry at the wafer surface combined with voltage, and the performance of the resultant structure may be adversely impacted by the remaining link to the Si substrate through a specific interconnect path.

Referring to FIG. 2 of the drawings, the present invention aims to overcome this problem by opening this path (at, sy, 30) after the specific process has been performed, and an exemplary process and integration scheme to achieve this will now be described in more detail.

In order to achieve the object of the invention in relation to the structure illustrated in FIG. 1 of the drawings, it is proposed to remove Cu from within a dual Damascene (or single Damascene) Cu stack using either dedicated chemistry or a reverse electroplating process, although it will be appreciated that other Cu (or metal) removal processes may be applicable, depending, among other things, on what metal is used for the interconnects.

Referring to FIG. 3 of the drawings, in general, in order to expose a Cu structure 36 for the purpose of removing it, a layer 32 of photoresist is deposited on a the upper barrier layer 21 and lithographically etched to create an exposed area 34 corresponding to the Cu structure 36, as shown in FIG. 3(a). The exposed area 34 (FIG. 3(b)) is then etched to remove the exposed portion of the barrier layer 2, thereby exposing the top of the Cu structure 36, and then the remaining photoresist layer is stripped (FIG. 3(c)).

Referring to FIG. 4 of the drawings, methods of Cu removal using adapted and selected chemistry which leave the barrier layer in tact are known. For example, nitric acid can be used for the selective etching of copper. Other techniques will, however, be well known to a person skilled in the art. However, in a standard Dual Damascene process, a barrier 39 (FIG. 4(a)) provided at the bottom of a via may stop Cu removal from continuing to the end of the Cu structure 36 required to be removed (FIG. 4(b)). Therefore, in a structure 36 such as that shown in FIG. 3(a), if this structure is required to be removed using adapted and selective chemistry (i.e. selective between the Cu and the barrier layer), then the interface between the upper via and the lower trench should be a Cu—Cu interface (FIG. 4(c)), i.e. it is necessary to use a metallisation sequence that results in a Cu—Cu interface at via level, so as to ensure that the entire Cu structure is removed (FIG. 4(d)). A Cu—Cu interface at via level can be provided, for example, by a known punch through process whereby a plasma treatment opens the bottom of the vias through metal carrier and/or copper. Alternatively, and referring to FIG. 5 of the drawings, if a chemical process is used to remove the Cu structure 36 that is not selective between the Cu and the barrier layer (e.g. Ta/TaN), dielectric liners 40 (FIG. 5(a)) may be provided on the side walls of the structure 36 so as to enable the Cu structure 36 and associated barrier layers 39 to be chemically removed, without degradation of the surrounding ILD. In yet another embodiment, the Cu structure can be removed by means of a known reverse electropolishing process, wherein reverse Cu electrolysis is achieved via a top contact at the upper metal level and a bottom contact to the Si substrate through direct W via plug 14 connections to the Cu path.

In the following, a complete exemplary embodiment of an integration process will be described in detail.

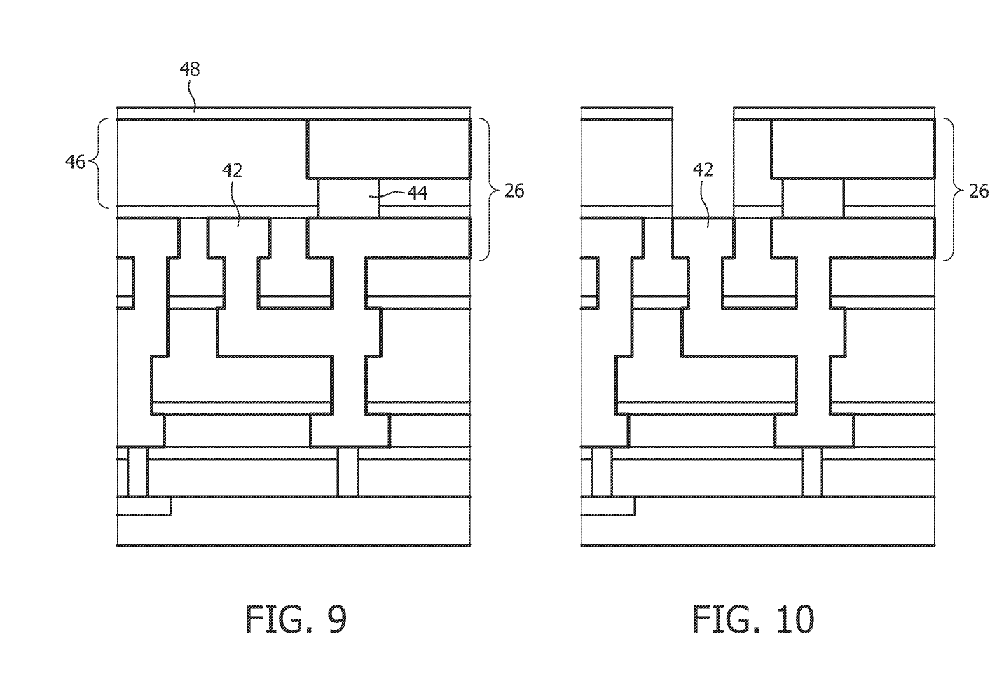

Starting with the structure illustrated in FIG. 6 of the drawings, a conventional dual damasceen structure is illustrated, with a second interconnect path 42 provided from the wafer surface to a point along the primary interconnect structure 36. A photoresist layer is provided on the upper barrier layer 21, lithographically patterned and etched to create an exposed area 34, following which the remaining photoresist layer is removed. Next, and referring to FIG. 7, a wet chemistry (or CVD) process is performed on top of the wafer surface and, by polarising the Cu line 36 via the Si substrate, a structure (such as the insulating portion 44 of a MIM capacitor) is deposited only at the exposed area 34 on the Metal n level of the interconnect stack, as shown in FIG. 8. The upper metal (n+1) level 46 is built by completing the conventional interconnect stack formation, including deposition of an upper barrier layer 48, as shown in FIG. 9.

Referring to FIG. 10 of the drawings, the interconnect stack is opened above the second interconnect path 42, by means of a conventional lithography and etching process, as before. In order to open the electrical path connecting the structure 26 to the environment, the Cu of the second path 42 and the intersection between the second path and the primary path 36 may be removed by means of wet chemistry (either selective, wherein Cu—Cu interfaces are provided at via level, or non-selective, wherein barrier layers are removed as well, in which case the path required to be removed is coated with dielectric liners by means of, for example, ALD deposition) or by means of the reverse electrolytic Cu process, as described above. In the latter case, it will be appreciated that the primary interconnect structure 36 is used for a second time, in order to provide the interconnect between the upper and lower contacts for the reverse electrolytic process.

In all cases, a dielectric CVD or spin-on deposition may be performed in respect of the newly-opened path, and associated to CMP, so as to enhance interconnect stack mechanical and reliability properties, as shown in FIG. 12. In more detail, if a cavity is let open at the surface of the wafer, there is a risk in respect of mechanical issues during the next metal level formation (interconnects, or packaging). Therefore, it could be necessary to fill an open trench at the top surface of the wafer. To achieve this partial filling, it is considered advantageous to use a CVD or spin on deposition of a dielectric on the top of the wafer. If this dielectric only aims at filling the trench, it could be a different material from the one required for upper metal level formation: therefore, it could be necessary to remove the dielectric in excess at the surface using a dedicated chemical mechanical plishing that flattens the top surface as illustrated in FIG. 12. Consequently, FIG. 12 illustrates a robust configuration that simultaneously address the ID description, and allows an easy way to perform any additional process on the wafers.

One significant advantage of the approach described herein is that a single and repeated structure can be defined to open/cut the path between different structures (areas, function, design) so that the opening process can be precisely tuned to successively achieve the required functionality.

Referring to FIG. 13 of the drawings, it will be appreciated that “structures” (such as a MIM capacitor) can be defined at the Cu interconnect side walls, rather than on the top as in the previous embodiment. Thus, a trench 50 is etched alongside the Metal n level trench 36a (FIG. 13(a)), the trench is filled with insulating material 52 (FIG. 13(b)) and the Metal n+1 level 46 is then formed, following which the trench and part of the vias connecting the Metal n and Metal n+1 layers is removed from the side (rather than the top) of the interconnect stack (FIG. 13(c)).

The techniques described above can be used in respect of local deposition within Cu interconnects of specific metallization layers, carbon nanotube growth, porous matrix formation (using, for example, aluminium, polysilicon matrices, etc), or any other process that requires the existence of a voltage threshold between the upper surface of the wafer and the Cu line when a potential cannot be directly applied to the whole wafer surface, as in the specific case of Cu ECD in dual damascene metallization, so as to improve performance of structures thus defined.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. A method of fabricating an electronic integrated circuit comprising:
providing at least one dielectric layer on a substrate, forming a primary metallic interconnect line from a first location through said dielectric layer to said substrate and a second interconnect path from said primary interconnect line to a second location, different from said first location,
creating a structure adjacent said primary interconnect line and
removing, via said second interconnect path, at least a portion of said primary interconnect line at the intersection between said primary interconnect line and said second interconnect path so as to form an open circuit in said primary interconnect line.

2. A method according to claim 1, wherein said integrated circuit comprises a multi-layer interconnect stack, and wherein aid first and second locations from which said primary interconnect line and second interconnect path respectively extend are laterally spaced from each other at an upper surface of the same interconnect layer n.

3. A method according to claim 2, wherein said structure is formed by creating an exposed area on said primary interconnect line at said first location, and forming said structure in the next interconnect layer n+1 of said stack.

4. A method according to claim 1, wherein said second interconnect path extends substantially vertically into the dielectric layer of the interconnect layer n and then substantially horizontally to intersect with said primary interconnect line.

5. A method according to claim 1, wherein said structure is formed alongside the primary interconnect line.

6. A method according to claim 1, wherein said second interconnect path and intersecting portion of the primary interconnect line are removed by chemical etching or a reverse metal electropolishing process.

7. A method according to claim 1, wherein creating a structure adjacent said primary interconnect line is achieved by performing a process step that includes the step of generating a voltage across said primary interconnect line.

8. An electronic integrated circuit fabricated in accordance with the method of claim 1.
